(19) United States
(12) Patent Application Publication
(10) Pub. No.: US 2019/0140104 A1
(43) Pub. Date: May 9, 2019

(54) SEMICONDUCTOR DEVICE AND METHOD FOR MANUFACTURING SAME

(71) Applicant: Sumitomo Electric Industries, Ltd., Osaka-shi (JP)

(72) Inventors: Miki Miyanaga, Itami-shi (JP); Kenichi Watatani, Itami-shi (JP); Hideaki Awata, Itami-shi (JP)

(21) Appl. No.: 16/099,786

(22) PCT Filed: Feb. 9, 2017
(86) PCT No.: PCT/JP2017/004768

§ 371 Date: Nov. 8, 2018

(30) Foreign Application Priority Data
Jun. 13, 2016 (JP) 2016-117125

(51) Int. Cl. H01L 29/786; H01L 29/66; H01L 29/417; H01L 29/423; H01L 21/44; H01L 21/477

(52) U.S. Cl. CPC H01L 29/78693; H01L 29/78696; H01L 29/66969; H01L 21/477; H01L 29/42384; H01L 21/44; H01L 29/41733

(57) ABSTRACT

Provided are a semiconductor device and a method for manufacturing the same, the device including a channel layer including an oxide semiconductor containing In, W, and Zn, a content of W relative to a total of In, W, and Zn in the channel layer being more than 0.01 atom % and less than or equal to 8.0 atom %, the channel layer including a first region, a second region, and a third region in this order, the first region including a first surface in contact with the gate insulating layer, the third region including a second surface opposite to the first surface, a content W3 (atom %) of W relative to a total of In, W, and Zn in the third region being larger than a content W2 (atom %) of W relative to a total of In, W, and Zn in the second region.

### TECHNICAL FIELD

The present invention relates to a semiconductor device and a method for manufacturing the semiconductor device.

The present application claims a priority based on Japanese Patent Application No. 2016-117125 filed on Jun. 13, 2016, the entire content of which is incorporated herein by reference.

### BACKGROUND ART

Conventionally, an amorphous silicon (a-Si) film has been used mainly for a semiconductor film serving as a channel layer of a TFT (thin film transistor), which is a semiconductor device, in a liquid crystal display device, a thin film EL (electroluminescence) display device, an organic EL display device, or the like.

In recent years, as a material to replace a-Si, a complex oxide containing indium (In), gallium (Ga), and zinc (Zn), i.e., an In-Ga-Zn-based complex oxide (also referred to as “IGZO”) has been drawing attention (for example, Japanese Patent Laying-Open No. 2008-199005 (Patent Literature 1)).

WO 2009/081885 (Patent Literature 2) discloses a field effect transistor having a semiconductor layer composed of a complex oxide including an In element, a Zn element, and one or more elements X selected from a group consisting of Zr, Hf, Ge, Si, Ti, Mn, W, Mo, V, Cu, Ni, Co, Fe, Cr, Nb, Al, B, Sc, Y, and lanthanoids, at the following atomic ratios (1) to (3):

In/(In+Zn)=0.2 to 0.8 (1)

In/(In+X)=0.29 to 0.99 (2)

Zn/(X+Zn)=0.29 to 0.99 (3).

### CITATION LIST

### Patent Literature

PTL 1: Japanese Patent Laying-Open No. 2008-199005

PTL 2: WO 2009/081885

### SUMMARY OF INVENTION

A semiconductor device according to one embodiment of the present invention relates to a semiconductor device including a gate insulating layer, and a channel layer disposed in contact with the gate insulating layer, the channel layer including an oxide semiconductor containing indium, tungsten, and zinc. In the semiconductor device, a content of the tungsten relative to a total of the indium, the tungsten, and the zinc in the channel layer is more than 0.01 atom % and less than or equal to 8.0 atom %. The channel layer includes a first region, a second region, and a third region in this order, the first region including a first surface in contact with the gate insulating layer, the third region including a second surface opposite to the first surface. A content W3 (atom %) of the tungsten relative to a total of the indium, the tungsten, and the zinc in the third region is larger than a content W2 (atom %) of the tungsten relative to a total of the indium, the tungsten, and the zinc in the second region.

A method for manufacturing a semiconductor device according to another embodiment of the present invention is a method for manufacturing the semiconductor device according to the above-described embodiment, and includes: forming a layer including the oxide semiconductor so that the layer is in contact with the gate insulating layer; and performing a heat treatment onto the layer including the oxide semiconductor at a temperature of more than or equal to 300° C.

### BRIEF DESCRIPTION OF DRAWINGS

FIG. 1 is a schematic plan view showing an exemplary arrangement of a channel layer, a source electrode, and a drain electrode in a semiconductor device according to one embodiment of the present invention.

FIG. 2 is a schematic cross sectional view showing an exemplary semiconductor device according to one embodiment of the present invention.

FIG. 3 is a schematic cross sectional view showing another exemplary semiconductor device according to one embodiment of the present invention.

FIG. 4 is a schematic cross sectional view showing an exemplary channel layer included in the semiconductor device according to one embodiment of the present invention.

FIG. 5 is a schematic cross sectional view showing an exemplary method for manufacturing the semiconductor device shown in FIG. 2.

FIG. 6 is a schematic cross sectional view showing the exemplary method for manufacturing the semiconductor device shown in FIG. 2.

FIG. 7 is a schematic cross sectional view showing the exemplary method for manufacturing the semiconductor device shown in FIG. 2.

FIG. 8 is a schematic cross sectional view showing the exemplary method for manufacturing the semiconductor device shown in FIG. 2.

FIG. 9 is a schematic cross sectional view showing the exemplary method for manufacturing the semiconductor device shown in FIG. 2.

FIG. 10 is a schematic cross sectional view showing the exemplary method for manufacturing the semiconductor device shown in FIG. 2.

FIG. 11 is a schematic cross sectional view showing the exemplary method for manufacturing the semiconductor device shown in FIG. 2.

### DETAILED DESCRIPTION

### Problem to be Solved by the Present Disclosure

A conventional TFT including a channel layer composed of an oxide semiconductor still has a room for improvement in terms of electric field effect mobility and the like. Hence, it is an object to provide a semiconductor device including an oxide semiconductor layer and attaining both high electric field effect mobility and high reliability.

### Advantageous Effect of the Present Disclosure

According to the above-described configuration, there can be provided a semiconductor device attaining both high electric field effect mobility and high reliability.

### Description of Embodiments

First, the following describes embodiments of the present invention.

[1] A semiconductor device according to one embodiment of the present invention includes a gate insulating layer, and a channel layer disposed in contact with the gate insulating layer, the channel layer including an oxide semiconductor containing indium (In), tungsten (W), and zinc (Zn). In the semiconductor device according to one embodiment of the present invention, a content of the W (atom %; hereinafter, also referred to as “W content of the channel layer”) relative to a total of the In, the W, and the Zn in the channel layer is more than 0.01 atom % and less than or equal to 8.0 atom %. The channel layer includes a first region, a second region, and a third region in this order, the first region including a first surface in contact with the gate insulating layer, the third region including a second surface opposite to the first surface. A content W3 (atom %) of the W relative to a total of the In, the W, and the Zn in the third region is larger than a content W2 (atom %) of the W relative to a total of the In, the W, and the Zn in the second region.

According to the semiconductor device of the present embodiment, both high electric field effect mobility and high reliability can be attained. The semiconductor device is specifically a TFT (thin film transistor).

[2] In the semiconductor device of the present embodiment, a ratio (W3/W2) of the contents W3 and the W2 of the W is preferably more than 1.0 and less than or equal to 4.0. This is advantageous in attaining both high electric field effect mobility and high reliability.

[3] In the semiconductor device of the present embodiment, a content W1 (atom %) of the W relative to a total of the In, the W, and the Zn in the first region may be larger than the W2 (atom %). This is advantageous in further improving the reliability of the semiconductor device.

[4] In the semiconductor device of the present embodiment, a content W1 (atom %) of the W relative to a total of the In, the W, and the Zn in the first region may be equal to or less than the W2 (atom %). This is advantageous in further improving the electric field effect mobility of the semiconductor device.

[5] In the semiconductor device of the present embodiment, a content of the Zn (atom %; hereinafter, also referred to as “Zn content of the channel layer”) relative to the total of the In, the W, and the Zn in the channel layer is preferably more than or equal to 1.2 atom % and less than 40 atom %, and an atomic ratio (hereinafter, also referred to as “Zn/W ratio of the channel layer”) of the Zn and the W in the channel layer is preferably more than 1.0 and less than 60. This is advantageous in further improving the electric field effect mobility and reliability of the semiconductor device.

[6] In the semiconductor device of the present embodiment, the channel layer preferably has an electric resistivity of more than or equal to 10⁻¹ Ωcm. This is advantageous in realizing a semiconductor device in which off current is small and on voltage is more than or equal to −3 V and less than or equal to 3 V.

[7] In the semiconductor device of the present embodiment, the channel layer preferably has an electron carrier concentration of more than or equal to 1×10¹³/cm³ and less than or equal to 9×10¹⁸/cm³. This is advantageous in realizing a semiconductor device in which off current is small and on voltage is more than or equal to −3 V and less than or equal to 3 V.

[8] In the semiconductor device of the present embodiment, the channel layer can further contain zirconium (Zr). A content of the Zr is preferably more than or equal to 1×10¹⁷ atms/cm³ and less than or equal to 1×10²⁰ atms/cm³. With the content of the zirconium therein, the reliability of the semiconductor device can be improved further.

[9] In the semiconductor device of the present embodiment, the channel layer can be composed of a nano crystal oxide or an amorphous oxide. This is advantageous in further increasing the electric field effect mobility and reliability of the semiconductor device.

[10] In the semiconductor device of the present embodiment, the third region is preferably in contact with a layer having an oxygen atom content of more than or equal to 10 atom % and less than or equal to 80 atom %. This is advantageous in realizing a semiconductor device in which W3 is larger than W2 and both high electric field effect mobility and high reliability are attained.

[11] In the semiconductor device of the present embodiment, the gate insulating layer preferably has an oxygen atom content of more than or equal to 10 atom % and less than or equal to 80 atom %. This is advantageous in realizing a semiconductor device in which W1 is larger than W2 and both high electric field effect mobility and high reliability are attained, and is particularly advantageous in improving the reliability of the semiconductor device.

[12] In the semiconductor device of the present embodiment, the gate insulating layer may have an oxygen atom content of more than or equal to 0 atom % and less than 10 atom %. This is advantageous in realizing a semiconductor device in which W1 is smaller than W2 and both high electric field effect mobility and high reliability are attained, and is particularly advantageous in improving the electric field effect mobility of the semiconductor device.

[13] A method for manufacturing a semiconductor device according to another embodiment of the present invention is a method for manufacturing the semiconductor device according to the foregoing embodiment, and includes: forming a layer including the oxide semiconductor so that the layer is in contact with the gate insulating layer; and performing a heat treatment onto the layer including the oxide semiconductor at a temperature of more than or equal to 300° C. According to the method for manufacturing the semiconductor device in the present embodiment, there can be manufactured a semiconductor device attaining both high electric field effect mobility and high reliability.

[14] In the method for manufacturing the semiconductor device according to the present embodiment, the temperature of the heat treatment is preferably less than or equal to 500° C. This is advantageous in forming the channel layer composed of the nano crystal oxide or the amorphous oxide to further improve the electric field effect mobility and reliability of the semiconductor device.

### Details of Embodiments of the Present Invention

### First Embodiment: Semiconductor Device

A semiconductor device according to the present embodiment includes: a gate insulating layer; and a channel layer disposed in contact with the gate insulating layer. The channel layer includes an oxide semiconductor containing In, W, and Zn. In the semiconductor device of the present embodiment, a W content of the channel layer (a content of W relative to a total of In, W, and Zn in the channel layer) is more than 0.01 atom % and less than or equal to 8.0 atom %. The channel layer includes a first region, a second region, and a third region in this order, the first region including a first surface in contact with the gate insulating layer, the third region including a second surface opposite to the first surface. A content W3 of W in the third region (a content of W relative to a total of In, W, and Zn in the third region) is larger than a content W2 of W in the second region (a content of W relative to a total of In, W, and Zn in the second region).

According to the semiconductor device of the present embodiment, both high electric field effect mobility and high reliability can be attained. Specifically, the semiconductor device is a TFT (thin film transistor).

Here, the following describes the reliability of the semiconductor device. The expression “high reliability of the semiconductor device” means that the characteristics of the semiconductor device are unlikely to be deteriorated by use thereof. Generally, reliability of a semiconductor device including an oxide semiconductor layer is changed according to a temperature of a heat treatment when manufacturing the semiconductor device. The reliability can be improved by increasing the temperature of the heat treatment. However, when the temperature of the heat treatment is increased, electric field effect mobility tends to be decreased. Therefore, it has been desired that the electric field effect mobility becomes unlikely to be decreased even at a high heat treatment temperature. In the present specification, the expression “both high electric field effect mobility and high reliability are attained” means that the electric field effect mobility is unlikely to be decreased even at a high heat treatment temperature and high reliability is obtained by the high heat treatment temperature.

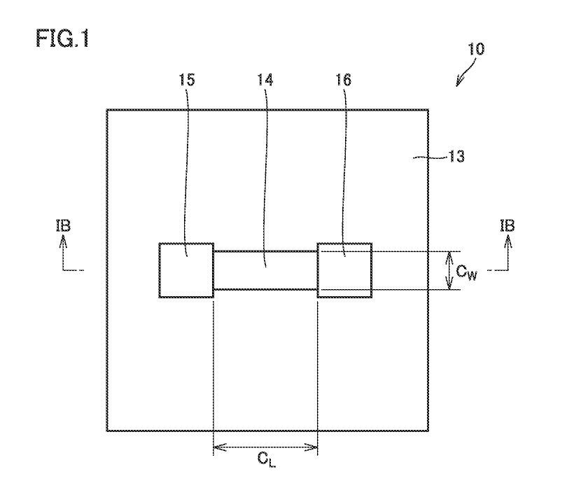

FIG. 1 is a schematic plan view showing an exemplary arrangement of a channel layer, a source electrode, and a drain electrode in a semiconductor device (TFT) according to one embodiment of the present invention. It should be noted that the semiconductor device according to one embodiment of the present invention preferably further includes a below-described “adjacent layer” disposed in contact with a third region of the channel layer; however, in the illustration of the semiconductor device in FIG. 1, the adjacent layer is omitted. A semiconductor device 10 shown in FIG. 1 includes: a substrate 11 (not shown in FIG. 1); a gate electrode 12 (not shown in FIG. 1) disposed on substrate 11; a gate insulating layer 13 disposed on gate electrode 12; a channel layer 14 disposed in contact with gate insulating layer 13; and a source electrode 15 and a drain electrode 16 disposed on channel layer 14 so as not to be in contact with each other. It should be noted that channel layer 14 is constituted of: a source electrode formation portion and a drain electrode formation portion just above which source electrode 15 and drain electrode 16 are respectively layered; and a channel portion disposed between the source electrode formation portion and the drain electrode formation portion.

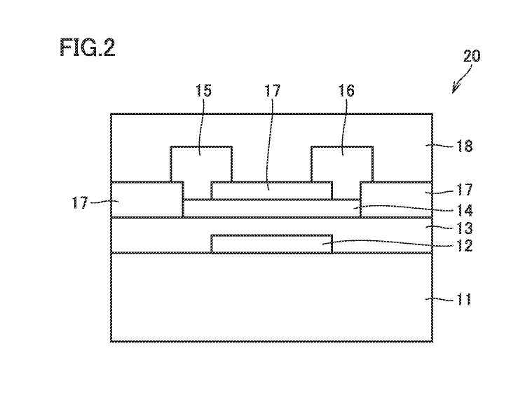

FIG. 2 is a schematic cross sectional view showing an exemplary semiconductor device (TFT) according to one embodiment of the present invention. A semiconductor device 20 shown in FIG. 2 includes: a substrate 11; a gate electrode 12 disposed on substrate 11; a gate insulating layer 13 disposed on gate electrode 12; a channel layer 14 disposed in contact with gate insulating layer 13; a source electrode 15 and a drain electrode 16 disposed on channel layer 14 so as not to be in contact with each other; an etch stopper layer 17 disposed on gate insulating layer 13 and channel layer 14 and provided with a contact hole; and a passivation layer 18 disposed on etch stopper layer 17, source electrode 15, and drain electrode 16. In semiconductor device 20 shown in FIG. 2, passivation layer 18 can be omitted.

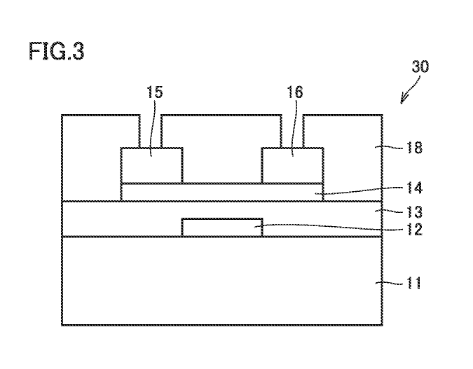

FIG. 3 is a schematic cross sectional view showing another exemplary semiconductor device (TFT) according to one embodiment of the present invention. A semiconductor device 30 shown in FIG. 3 further includes a passivation layer 18 disposed on gate insulating layer 13, source electrode 15, and drain electrode 16. A difference from semiconductor device 20 shown in FIG. 2 lies in that semiconductor device 30 has no etch stopper layer 17.

With reference to figures, the following describes a semiconductor device according to one embodiment of the present invention in detail.

(1) Channel Layer

Channel layer 14 includes an oxide semiconductor containing In, W, and Zn, and is a layer disposed in contact with gate insulating layer 13. Channel layer 14 can be formed on gate insulating layer 13 by a sputtering method employing an oxide sintered material containing In, W, and Zn as a sputtering target, for example. The method for forming channel layer 14 (oxide semiconductor layer) using the sputtering method is advantageous in attaining both high electric field effect mobility and high reliability in the semiconductor device to be obtained. The film thickness of channel layer 14 is, for example, more than or equal to 2 nm and less than or equal to 100 nm, is preferably more than or equal to 10 nm, and is more preferably more than or equal to 20 nm. Moreover, the film thickness of channel layer 14 is preferably less than or equal to 80 nm, and is more preferably less than or equal to 40 nm.

(1-1) First to Third Regions of Channel Layer

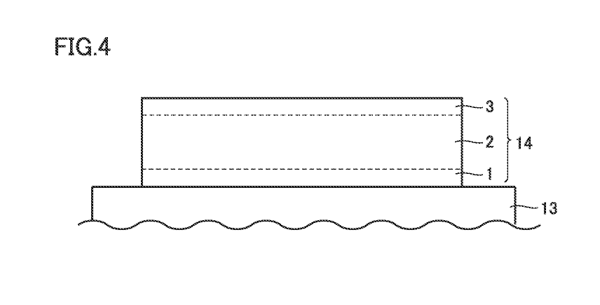

As shown in FIG. 4, channel layer 14 includes: a first region 1, a second region 2, and a third region 3 in this order. First region 1 includes a first surface in contact with gate insulating layer 13. Third region 3 includes a second surface opposite to the first surface. Second region 2 is a region between first region 1 and third region 3.

In the semiconductor device according to one embodiment of the present invention, a content W3 (atom %) of W in third region 3 is larger than a content W2 (atom %) of W in second region 2. Accordingly, a semiconductor device can be realized in which off current is small and on voltage is positive (i.e., normally off) and in which both high electric field effect mobility and high reliability can be attained.

Third region 3 is a region generally called “back channel”, and is often in contact with the etch stopper layer, the passivation layer, the protective layer, or the like. The thickness of third region 3 is, for example, more than 0 nm and less than or equal to 10 nm, is preferably more than or equal to 0.5 nm, and is preferably less than or equal to 5 nm.

Second region 2 is a region between first region 1 and third region 3, and content W2 (atom %) of W therein is less than content W3 (atom %) of W in third region 3. In order to attain both high electric field effect mobility and high reliability, a ratio (W3/W2) of W3 and W2 is preferably more than 1.0 and less than or equal to 4.0, and is more preferably more than or equal to 1.2 and less than or equal to 4.0.

First region 1 is a region generally called “front channel”. The thickness of first region 1 is, for example, more than 0 nm and less than or equal to 10 nm and is preferably more than or equal to 0.5 nm, and is preferably less than or equal to 5 nm.

Content W1 (atom %) of W in first region 1 (content of W relative to the total of In, W, and Zn in first region 1) may be more than W2 (atom %). This is advantageous in further improving the reliability of the semiconductor device. For the reliability of the semiconductor device, a ratio (W1/W2) of W1 and W2 is preferably more than or equal to 1.2 and less than or equal to 4.0.

Alternatively, W1 may be equal to or less than W2. This is advantageous in further improving the electric field effect mobility of the semiconductor device. For the electric field effect mobility of the semiconductor device, the ratio (W1/W2) of W1 and W2 is preferably more than or equal to 0.25 and less than or equal to 1.0.

A secondary ion mass spectrometer (SIMS) can be used to check whether or not channel layer 14 includes second region 2 and third region 3, and can be used to measure the value of W3/W2. That is, the SIMS is used to analyze the W concentration of channel layer 14 in the depth direction. The W concentration is obtained as the number of counts of secondary ions originated from W per 1 cm³. Existence of second region 2 and third region 3 can be confirmed when a larger number of counts are obtained in the region including the outer surface (second surface) of channel layer 14 and the number of counts in a region deeper than the foregoing region is less than the foregoing number of counts. The region having the larger number of counts corresponds to third region 3 and the region having the smaller number of counts corresponds to second region 2. The value of W3/ W2 is found as (the number of counts of the region indicating the larger number of counts)/(the number of counts of the region indicating the smaller number of counts). It should be noted that in the measurement using the SIMS, as the number of counts of secondary ions originated from W at a certain specific depth, the average value of the numbers of counts measured at three arbitrary points in a plane at the depth is employed.

Also, the SIMS can be used to find the value of W1/W2 in the same manner as that described above based on the number of counts of secondary ions originated from W in the depth direction. As described above, W1 may be larger than, smaller than, or equal to W2. As with the value of W3/W2, the value of W1/W2 is found as a ratio of the numbers of counts. From second region 2 to the first surface (surface at the gate insulating layer 13 side) of channel layer 14, the number of counts of secondary ions originated from W is measured in the depth direction. When the number of counts in a region including the first surface is higher or lower than the number of counts in second region 2, that region can be considered as first region 1. On the other hand, when the number of counts of secondary ions originated from W is measured from second region 2 to the first surface of channel layer 14 in the depth direction and the number of count is substantially unchanged, it can be considered that there is first region 1 having W1 with the same value as that of W2.

Moreover, a scanning transmission electron microscope with an energy dispersive X-ray spectrometer (EDS) can be used to check whether channel layer 14 includes second region 2 and third region 3 and can be used to measure the value of W3/W2. That is, the existence of second region 2 and third region 3 can be confirmed when a larger W content is obtained in the region including the outer surface (second surface) of channel layer 14 as a result of observation of a cross section of the semiconductor device using the above microscope and when the W content of the region deeper than the foregoing region is less than the foregoing W content. The region having a larger W content corresponds to third region 3, and the region having a smaller W content corresponds to second region 2. The value of W3/ W2 is found as (the W content of the region indicating the larger W content)/(the W content of the region indicating the smaller W content). It should be noted that in the measurement using the scanning transmission electron microscope with the energy dispersive X-ray spectrometer (EDS), as a W content at a certain specific depth, the average value of W contents measured at three arbitrary points in a plane at the depth is employed.

Also, the scanning transmission electron microscope with the energy dispersive X-ray spectrometer (EDS) can be used to find the value of W1/W2 in the same manner as that described above. As described above, W1 may be larger than, smaller than, or equal to W2. As with the value of W3/W2, the value of W1/W2 is found as a ratio of the W contents obtained using the above-described microscope. From second region 2 to the first surface (surface at the gate insulating layer 13 side) of channel layer 14, the W content is measured in the depth direction. When the W content in the region including the first surface is higher or lower than the W content of second region 2, the region can be considered as first region 1. On the other hand, when the W content is measured from second region 2 to the first surface of channel layer 14 in the depth direction and the W content is substantially unchanged, it can be considered that there is first region 1 having W1 with the same value as that of W2.

A sample for the measurement by the scanning transmission electron microscope is produced by thinning through an ion milling method. Conditions of the EDS analysis are as follows: an acceleration voltage of 200 kV; a beam diameter y of 0.1 nm; an energy resolution of 140 eV; an X-ray take-off angle of 21.9°; and a measurement time of 30 seconds.

Normally, the SIMS is used to check whether channel layer 14 includes second region 2 and third region 3 and is used to measure the value of W3/ W2 and the value of W1/W2. However, when the analysis by the SIMS cannot be performed due to some reason, the scanning transmission electron microscope with the EDS is used.

(1-2) Tungsten Content of Channel Layer

In order to attain both high electric field effect mobility and high reliability, the content of W (W content of channel layer 14) relative to the total of In, W, and Zn in channel layer 14 is more than 0.01 atom % and less than or equal to 8.0 atom %, is preferably more than or equal to 0.6 atom %, is preferably less than or equal to 5 atom %, and is more preferably less than or equal to 3 atom %. When the W content of channel layer 14 is less than or equal to 0.01 atom %, the reliability of the semiconductor device is decreased. When the W content of channel layer 14 is more than 8 atom %, the electric field effect mobility of the semiconductor device is decreased.

The W content of channel layer 14 herein refers to the average value of the W content of the whole of channel layer 14 including first region 1, second region 2, and third region 3. The W content of channel layer 14 is measured by RBS (Rutherford back-scattering analysis). The W content of channel layer 14 can be expressed by the following formula using W content W1 of first region 1, W content W2 of second region 2, and W content W3 of third region 3: the W content of channel layer 14=(W1×the film thickness of first region 1+W2×the film thickness of second region 2+W3×the film thickness of third region 3)/(the film thickness of first region 1+the film thickness of second region 2+the film thickness of third region 3). Each of the property values (the W content and film thickness of each region) described at the right side of the above-described formula is measured by the RBS. Depending on the film thickness of each region, it may be difficult to separate the respective regions from one another and a result of measurement assuming that they are the same layer may be obtained. In this case, this result of measurement is considered as the W content of channel layer 14.

(1-3) Zn Content and Zn/W Ratio of Channel Layer

A content of Zn (Zn content of channel layer 14) relative to the total of In, W, and Zn in channel layer 14 is preferably more than or equal to 1.2 atom % and less than 40 atom %, and an atomic ratio (Zn/W ratio of channel layer 14) of Zn and W in channel layer 14 is preferably more than 1.0 and less than 60. This is advantageous in further improving the electric field effect mobility and reliability of the semiconductor device.

When the Zn content of channel layer 14 is less than 1.2 atom %, the effect of improving the reliability of the semiconductor device can become insufficient. When the Zn content of channel layer 14 is more than or equal to 40 atom %, the effect of improving the electric field effect mobility of the semiconductor device can become insufficient.

In order to further improve the electric field effect mobility and reliability of the semiconductor device, the Zn content of channel layer 14 is more preferably more than or equal to 3 atom %, is further preferably more than or equal to 11 atom %, is more preferably less than or equal to 30 atom %, and is further preferably less than 20 atom %.

When the Zn/W ratio of channel layer 14 is less than or equal to 1.0 or is more than or equal to 60, the effect of improving the reliability of the semiconductor device can become insufficient. The Zn/W ratio of channel layer 14 is more preferably more than or equal to 3.0, is further preferably more than or equal to 5.0, and is more preferably less than or equal to 35.

Moreover, for improvement in the reliability of the semiconductor device, the atomic ratio of In relative to the total of In and Zn in channel layer 14 (In/(In+Zn) atomic ratio) is preferably more than 0.8.

(1-4) Electric Resistivity of Channel Layer

Channel layer 14 preferably has an electric resistivity of more than or equal to 10⁻¹Ωcm. This is advantageous in realizing a semiconductor device in which off current is small and on voltage is more than or equal to −3 V and less than or equal to 3 V. Although an oxide including indium has been known as a transparent conducting film, a film having an electric resistivity of less than 10⁻¹Ωcm is general as a film used for such a transparent conducting film as described in Japanese Patent Laying-Open No. 2002-256424, for example. On the other hand, channel layer 14 of the semiconductor device of the present embodiment desirably has an electric resistivity of more than or equal to 10⁻¹Ωcm. In order to achieve such an electric resistivity, it is preferable to comprehensively review the W content, Zn content, and Zn/W ratio of channel layer 14.

(1-5) Electron Carrier Concentration of Channel Layer

The electron carrier concentration of channel layer 14 is preferably more than or equal to 1×10¹³/cm³ and less than or equal to 9×10¹⁸/cm³. This is advantageous in realizing a semiconductor device in which off current is small and on voltage is more than or equal to −3 V and less than or equal to 3 V. When the electron carrier concentration is less than 1×10¹³/cm³, the electric field effect mobility becomes too small. This is likely to make it difficult for channel layer 14 to function as a channel layer. When the electron carrier concentration is more than 9×10¹⁸/cm³, the off current becomes too high. This is likely to make it difficult for channel layer 14 to function as a channel layer.

(1-6) Another Element that can be Included in Channel Layer

Channel layer 14 can further contain zirconium (Zr). In this case, the content of Zr is preferably more than or equal to 1×10¹⁷ atms/cm³ and less than or equal to 1×10²⁰ atms/cm³. Accordingly, the reliability of the semiconductor device can be further improved. Generally, Zr is often applied to an oxide semiconductor layer in order to improve thermal stability, thermal resistance, and chemical resistance, or in order to reduce S value or off current; however, in the present invention, it has been newly found that the reliability can be improved when used together with W and Zn. The Zr content in channel layer 14 is measured by analyzing channel layer 14 in the depth direction using the secondary ion mass spectrometer (SIMS) to find an atomic number per 1 cm³. The Zr content in channel layer 14 is the average value thereof in the whole of channel layer 14, i.e., the average values of Zr contents measured at arbitrary three points in the film thickness direction.

When the content of Zr is less than 1×10¹⁷ atms/cm³, no improvement in reliability is observed. When the content of Zr is more than 1×10²⁰ atms/cm³, the reliability tends to be decreased. In order to improve the reliability, the content of Zr is more preferably more than or equal to 1×10¹⁸ atms/cm³, and is more preferably less than or equal to 1×10¹⁹ atms/cm³.

It should be noted that the content of an inevitable metal other than In, W, Zn, and Zr relative to the total of In, W, and Zn in channel layer 14 is preferably less than or equal to 1 atom %.

(1-7) Crystal Structure of Channel Layer

In order to improve the electric field effect mobility and reliability of the semiconductor device, the oxide semiconductor included in channel layer 14 is preferably composed of a nano crystal oxide or an amorphous oxide.

In the present specification, the term “nano crystal oxide” refers to an oxide for which no peak resulting from crystal is observed and only a broad peak called “halo” appearing at the low angle side is observed in an X-ray diffraction measurement under below-described conditions, and for which a ring-like pattern is observed when performing transmission electron beam diffraction measurement in a minute region under below-described conditions using a transmission electron microscope. The term “ring-like pattern” encompasses a case where spots are gathered to form a ring-like pattern.

Moreover, in the present specification, the term “amorphous oxide” refers to an oxide for which no peak resulting from crystal is observed and only a broad peak called “halo” appearing at the low angle side is observed in the X-ray diffraction measurement under below-described conditions, and for which the unclear pattern called “halo” is also observed even when performing transmission electron beam diffraction measurement in a minute region under the below-described conditions using a transmission electron microscope.

(X-Ray Diffraction Measurement Conditions)

Measurement method: In-plane method (slit collimation method);

X-ray generator: anticathode Cu, output of 50 kV 300 mA;

Detector: scintillation counter;

Incidence portion: slit collimation;

Soller slit: incidence side vertical divergence angle of 0.48°,
light receiving side vertical divergence angle of 0.41°;

Slit: incidence side S1=1 mm * 10 mm,
light receiving side S2=0.2 mm * 10 mm;

Scanning condition: Scanning axis 2θχ/φ;

Scanning mode: Step measurement, scanning range of 10° to 80°, step width of 0.1°;
Step time: 8 sec.

(Transmission Electron Beam Diffraction Measurement Conditions)

Measurement method: microscopic electron beam diffraction method,

Acceleration voltage: 200 kV,

Beam diameter: the same as or equivalent to the film thickness of the channel layer to be measured.

If channel layer 14 is composed of the nano crystal oxide, the ring-like pattern is observed as described above and no spot-like pattern is observed when performing transmission electron beam diffraction measurement in the minute region under the above conditions. On the other hand, an oxide semiconductor film disclosed in, for example, Japanese Patent No. 5172918 includes crystal oriented toward the c axis in a direction perpendicular to the surface of the film. When the nano crystal in the minute region is thus oriented in a certain direction, a spot-like pattern is observed. When channel layer 14 is composed of the nano crystal oxide, the nano crystal is of non-orientation or has a random orientation, i.e., is not oriented toward the surface of the film when at least observing a plane (film cross section) perpendicular to the plane of the film. That is, the crystal axis thereof is not oriented in the film thickness direction.

In order to improve field effect mobility, channel layer 14 is more preferably composed of the amorphous oxide. For example, when the Zn content of channel layer 14 is more than 10 atom %, when the W content is more than or equal to 0.4 atom %, and when the content of Zr is more than or equal to 1×10 ^{l7} atms/cm³, channel layer 14 is likely to be an amorphous oxide and the amorphous oxide is stable up to a higher heat treatment temperature.

(2) Adjacent Layer

The semiconductor device can further include a layer disposed in contact with third region 3 of channel layer 14. In the present specification, this layer is also referred to as “adjacent layer”. The adjacent layer is preferably in contact with at least a portion of the second surface (the surface opposite to the gate insulating layer 13 side) of channel layer 14. The semiconductor device may have two or more adjacent layers.

The adjacent layer is preferably an oxygen-atom-containing layer having an oxygen atom content of more than or equal to 10 atom % and less than or equal to 80 atom %. This facilitates realization of a semiconductor device that facilitates formation of channel layer 14 including third region 3 and second region 2 and having W3 larger than W2 and that accordingly attains both high electric field effect mobility and high reliability as described below. Examples of the adjacent layer include insulating layers such as the etch stopper layer, the passivation layer, and the protective layer. In order to attain both high electric field effect mobility and high reliability, each of the insulating layers such as the etch stopper layer, the passivation layer, and the protective layer is preferably a SiOx layer, a SiOxNy layer, or an AlxOy layer formed by chemical vapor deposition, physical vapor deposition, or the like. These insulating layers may include hydrogen atoms.

The content of oxygen atoms can be quantified by RBS, X-ray photoelectron spectroscopy, or WDS type X-ray fluorescence X-ray analysis. The content of the oxygen atoms is calculated by the atomic number of the oxygen atoms relative to the total atomic number of silicon, metal atoms, oxygen atoms, and nitrogen atoms in the adjacent layer (=the number of oxygen atoms/(the number of silicon atoms+the number of metal atoms+the number of oxygen atoms+the number of nitrogen atoms)). In the measurement of the content of the oxygen atoms, hydrogen atoms are not taken into consideration.

One of specific examples of the adjacent layer is etch stopper layer 17 included in semiconductor device 20 shown in FIG. 2. Another example of the adjacent layer is passivation layer 18 included in semiconductor device 30 shown in FIG. 3.

Examples of etch stopper layer 17 having an oxygen atom content of more than or equal to 10 atom % and less than or equal to 80 atom % include a layer composed of silicon oxide (SiOx), silicon oxynitride (SiOxNy), aluminum oxide (AlxOy), or the like, and preferably include a layer composed of silicon oxide (SiOx) or silicon oxynitride (SiOxNy). Etch stopper layer 17 may be a combination of layers composed of different materials.

Examples of passivation layer 18 having an oxygen atom content of more than or equal to 10 atom % and less than or equal to 80 atom % include a layer composed of silicon oxide (SiOx), silicon oxynitride (SiOxNy), aluminum oxide (AlxOy), or the like, and preferably include a layer composed of silicon oxide (SiOx) or silicon oxynitride (SiOxNy). For example, passivation layer 18 not serving as the adjacent layer, such as passivation layer 18 included in semiconductor device 20 shown in FIG. 2, may be composed of at least one of the above-described elements, silicon nitride (SiNx) or the like. Passivation layer 18 may be a combination of layers composed of different materials.

The adjacent layer is preferably an oxide layer or an oxynitride layer including at least one of silicon and aluminum. Particularly, when each of the layers referred to as the etch stopper layer, the passivation layer, the protective layer, and the like is an oxide layer or oxynitride layer including silicon, it is advantageous in increasing W content W3 of third region 3 of channel layer 14 to be larger than W content W2 of second region 2. Accordingly, it is advantageous in increasing the electric field effect mobility and reliability of the semiconductor device.

At least a part of W contained in third region 3 of channel layer 14 is preferably bound to at least one of silicon and/or aluminum included in the adjacent layer in contact with third region 3. Accordingly, the electric field effect mobility and reliability of the semiconductor device can be improved further. All of W contained in third region 3 does not need to be bound to silicon and/or aluminum, and a part of W may be bound to silicon and/or aluminum.

The adjacent layer is preferably at least one of a nano crystal layer and an amorphous layer. Accordingly, channel layer 14 formed in contact therewith is affected by the crystallinity of the adjacent layer and is accordingly likely to be a layer composed of a nano crystal oxide or an amorphous oxide, whereby the electric field effect mobility and reliability of the semiconductor device can be improved further.

The whole of the adjacent layer may be at least one of the nano crystal oxide and amorphous oxide, or a portion of the adjacent layer in contact with channel layer 14 may be at least one of the nano crystal oxide or the amorphous oxide. In the latter case, the portion that is at least one of the nano crystal oxide and the amorphous oxide may be the whole of a portion of the adjacent layer in the film surface direction or may be a portion of a surface in contact with channel layer 14.

(3) Gate Insulating Layer

Although the material of gate insulating film 13 should not be particularly limited, the material of gate insulating layer 13 is preferably silicon oxide (SiOx), silicon nitride (SiNx), silicon oxynitride (SiOxNy) or the like in view of the insulating property. Gate insulating layer 13 may be an oxygen-atom-containing layer having an oxygen atom content of more than or equal to 10 atom % and less than or equal to 80 atom %. This facilitates formation of channel layer 14 having W1 larger than W2 as described below in detail. W1/W2>1.0 is advantageous in further improving the reliability of the semiconductor device. The content of oxygen atoms can be quantified by RBS, X-ray photoelectron spectroscopy, or WDS type X-ray fluorescence X-ray analysis.

Alternatively, gate insulating layer 13 may be a layer having an oxygen atom content of less than 10 atom %. This facilitates formation of channel layer 14 having W1 equal to or less than W2 as described below in detail. W1/W2 1.0 is advantageous in further improving the electric field effect mobility of the semiconductor device.

(4) Source Electrode and Drain Electrode

Although source electrode 15 and drain electrode 16 should not be particularly limited, each of source electrode 15 and drain electrode 16 is preferably a Mo electrode, a Ti electrode, a W electrode, an Al electrode, a Cu electrode, or the like because these electrodes have high oxidation resistances, low electric resistances, and low contact electric resistances with respect to channel layer 14. Each of source electrode 15 and drain electrode 16 may include a plurality of metals and may have a layered structure such as a layered structure of Mo/Al/Mo, for example.

(5) Substrate and Gate Electrode

Although substrate 11 should not be particularly limited, substrate 11 is preferably a quartz glass substrate, a non-alkali glass substrate, an alkaline glass substrate, or the like in order to increase transparency, price stability, and surface smoothness. Although gate electrode 12 should not be particularly limited, gate electrode 12 is preferably a Mo electrode, a Ti electrode, a W electrode, an Al electrode, a Cu electrode, or the like because these electrodes have high oxidation resistances and low electric resistances. Gate electrodes 12 may be a layered structure such as a Mo/Al/Mo layered structure, for example.

### Second Embodiment: Method for Manufacturing Semiconductor Device

A method for manufacturing a semiconductor device according to the present embodiment is a method for manufacturing the above-described semiconductor device according to the first embodiment. In order to efficiently manufacture the semiconductor device attaining both high electric field effect mobility and high reliability, the method for manufacturing the semiconductor device according to the present embodiment preferably includes the steps of:

forming a layer including the above-described oxide semiconductor so that the layer is in contact with the gate insulating layer; and

performing a heat treatment onto the layer including the oxide semiconductor at a temperature of more than or equal to 300° C. The temperature of the heat treatment is more preferably more than or equal to 400° C., is further preferably more than or equal to 450° C., and is preferably less than or equal to 500° C.

By performing the heat treatment onto the layer including the oxide semiconductor at the temperature of more than or equal to 300° C., the W element can be diffused in the layer including the oxide semiconductor containing In, W, and Zn, whereby third region 3 having a higher W content than that of second region 2 is formed in channel layer 14. It should be noted that the W content as a whole of the layer including the oxide semiconductor is not changed before and after the diffusion of W element, and a distribution of W content satisfying W3>W2 is provided due to the W element moving from the region to be second region 2 to third region 3. As described below in detail, in order to form third region 3 having a W content higher than that of second region 2, the above-described heat treatment is preferably performed after forming the adjacent layer.

The formation of third region 3 provides both high electric field effect mobility and high reliability to the semiconductor device (for example, TFT) to be obtained.

When the temperature of the heat treatment is less than 300° C., the W element is unlikely to be diffused, with the result that it becomes difficult to form third region 3 satisfying W3>W2.

In order to diffuse the W element by the heat treatment, the heat treatment is preferably performed after forming the adjacent layer in contact with the outer surface (the second surface=the surface opposite to the gate insulating layer 13 side) of the layer including the oxide semiconductor and formed on gate insulating layer 13, and the adjacent layer is more preferably an oxygen-atom-containing layer having an oxygen atom content of more than or equal to 10 atom % and less than or equal to 80 atom %. This facilitates realization of a semiconductor device that facilitates formation of channel layer 14 including third region 3 and second region 2 and having W3 larger than W2 and that accordingly attains both high electric field effect mobility and high reliability. Specific examples of the adjacent layer includes insulating layers such as the etch stopper layer, the passivation layer, and the protective layer as described above, for example.

In order to diffuse the W element using the adjacent layer, the adjacent layer particularly preferably has an oxygen atom content of more than or equal to 10 atom % and less than or equal to 80 atom %. Accordingly, the W element in the layer including the oxide semiconductor can be diffused in the direction of the adjacent layer (toward the second surface of the layer including the oxide semiconductor), thereby providing the distribution of the W content satisfying W3>W2. When the oxygen atom content of the adjacent layer is less than 10 atom %, the W element is unlikely to be diffused.

On the other hand, by the heat treatment, the W element in the layer including the oxide semiconductor can be diffused in the direction of gate insulating layer 13. In order to diffuse the W element in the direction of gate insulating layer 13, gate insulating layer 13 is preferably an oxygen-atom-containing layer having an oxygen atom content of more than or equal to 10 atom % and less than or equal to 80 atom %. This facilitates formation of first region 1 that satisfies W1 >W2. W1/W2>1.0 is advantageous in further improving the reliability of the semiconductor device.

On the other hand, when the oxygen atom content of gate insulating layer 13 is less than 10 atom %, the W element is unlikely to be diffused in the direction of gate insulating layer 13, with the result that W1 tends to be equal to or less than W2. W1/W2<1.0 is advantageous in further improving the electric field effect mobility of the semiconductor device.

The temperature of the heat treatment for diffusing the W element using the adjacent layer and gate insulating layer 13 is preferably more than or equal to 300° C. and is preferably less than or equal to 500° C. as described above. When the heat treatment temperature is less than or equal to 500° C., channel layer 14 constituted of the nano crystal oxide or the amorphous oxide can be likely to be obtained. This is advantageous in improving the electric field effect mobility and reliability of the semiconductor device. When the heat treatment temperature is more than 500° C., the electric resistance of the electrode becomes too high, with the result that the semiconductor device may fail to operate.

The atmosphere of the heat treatment for diffusing the W element using the adjacent layer and gate insulating layer 13 should not be particularly limited and may be various types of atmospheres such as atmospheric air, nitrogen gas, nitrogen gas-oxygen gas, argon gas, argon-oxygen gas, vapor-containing atmospheric air, vapor-containing nitrogen, and the like. Preferably, the atmosphere of the heat treatment is nitrogen gas. In order to diffuse the W element effectively, the heat treatment preferably includes: a first heat treatment step performed in atmospheric air under an atmospheric pressure; and a second heat treatment step performed in a nitrogen gas under an atmospheric pressure after the first heat treatment step.

A pressure of the atmosphere in the heat treatment can be an atmospheric pressure, a reduced pressure (for example, less than 0.1 Pa), or an increased pressure (for example, 0.1 Pa to 91MPa), but is preferably the atmospheric pressure. The heat treatment time (total of the first and second heat treatment steps when the first and second heat treatment steps are included) can be, for example, about 3 minutes to 2 hours and is preferably about 10 minutes to 90 minutes.

The heat treatment after forming the adjacent layer and gate insulating layer 13 each having an oxygen atom content of more than or equal to 10 atom % and less than or equal to 80 atom % is also effective in controlling the electric resistivity, electron carrier concentration, and the like of channel layer 14 to fall within the above-described preferable ranges.

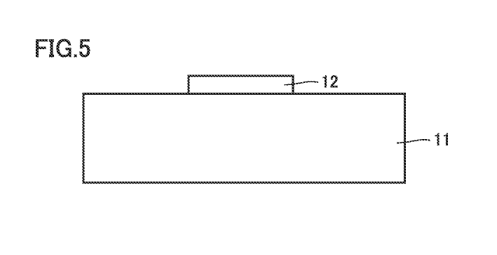

Next, the following more specifically describes a method for manufacturing the semiconductor device according to the present embodiment. First, a method for manufacturing semiconductor device 20 shown in FIG. 2 will be described. With reference to FIG. 5 to FIG. 11, this manufacturing method preferably includes the steps of:

forming gate electrode 12 on substrate 11 (FIG. 5);

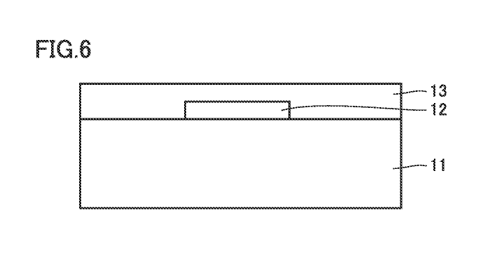

forming gate insulating layer 13 on gate electrode 12 (FIG. 6);

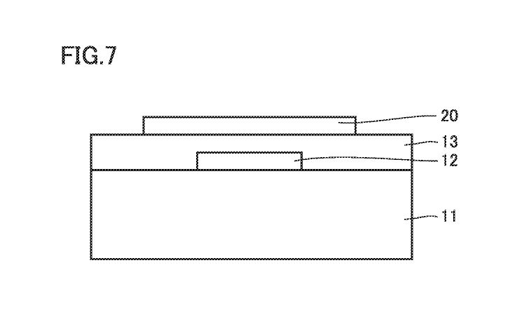

forming layer 20 including the oxide semiconductor on and in contact with gate insulating layer 13 (FIG. 7);

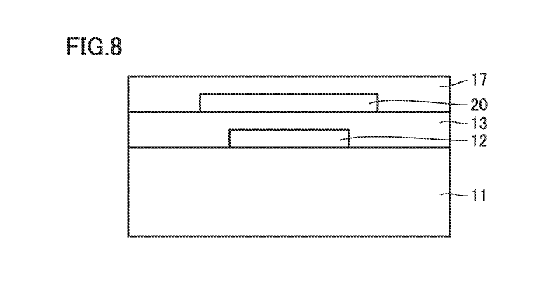

forming etch stopper layer 17 on layer 20 including the oxide semiconductor (FIG. 8);

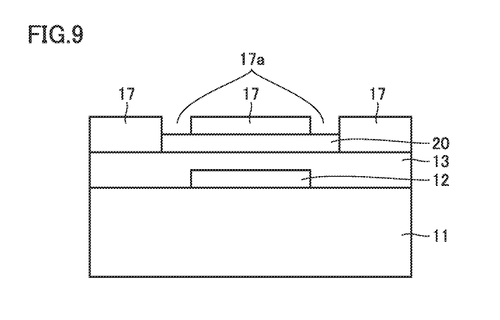

forming contact hole 17a in etch stopper layer 17 (FIG. 9);

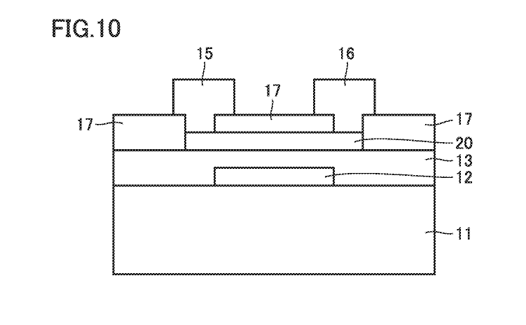

forming source electrode 15 and drain electrode 16 on layer 20 including the oxide semiconductor and on etch stopper layer 17, so as not to be in contact with each other (FIG. 10);

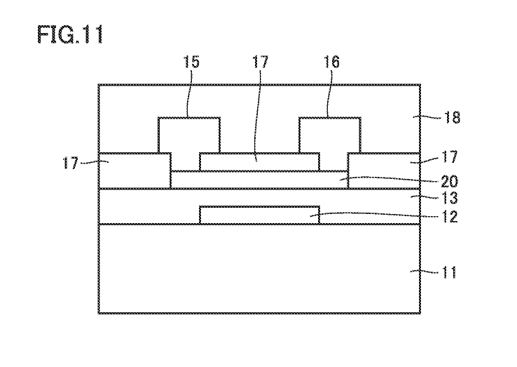

forming passivation layer 18 on etch stopper layer 17, source electrode 15, and drain electrode 16 (FIG. 11); and

obtaining semiconductor device 20 including channel layer 14 by performing a heat treatment onto layer 20 including the oxide semiconductor at a temperature of more than or equal to 300° C. (FIG. 2).

(1-1) Step of Forming Gate Electrode

With reference to FIG. 5, this step is a step of forming gate electrode 12 on substrate 11. Specific examples of substrate 11 and gate electrode 12 are as described above. Although the method for forming gate electrode 12 should not be particularly limited, the method for forming gate electrode 12 is preferably a vacuum deposition method, the sputtering method, or the like because a large area of gate electrode 12 can be uniformly formed on the main surface of substrate 11 by these methods.

(1-2) Step of Forming Gate Insulating Layer

With reference to FIG. 6, this step is a step of forming gate insulating layer 13 on gate electrode 12. The material of gate insulating layer 13 is as described above. Although a method for forming gate insulating layer 13 should not be particularly limited, the method for forming gate insulating film 13 is preferably a plasma CVD (chemical vapor deposition) method or the like because a large area of gate insulating layer 13 can be uniformly formed and an insulating property can be secured by the plasma CVD method.

(1-3) Step of Forming Layer Including Oxide Semiconductor

With reference to FIG. 7, this step is a step of forming layer 20 including the oxide semiconductor on and in contact with gate insulating layer 13. Layer 20 including the oxide semiconductor is preferably formed by a method including a film formation step using a sputtering method in which an oxide sintered material containing In, W, and Zn is employed as a target. This is advantageous in obtaining a semiconductor device attaining both high electric field effect mobility and high reliability.

The sputtering method refers to a method for forming a film composed of atoms from a target disposed to face a substrate in a film formation chamber in the following manner: voltage is applied to the target and a surface of the target is sputtered by noble gas ions to release atoms of the target and accordingly deposit them on the substrate.

As a method for forming the oxide semiconductor layer, not only the sputtering method but also a pulse laser vapor deposition (PLD) method, a heating deposition method, and the like have been conventionally proposed; however, due to the above-described reason, the sputtering method is preferably used.

As the sputtering method, a magnetron sputtering method, a facing target sputtering method, or the like can be used. As an atmospheric gas during the sputtering, Ar gas, Kr gas, and Xe gas can be used, and may be mixed with and used together with oxygen gas.

The heat treatment may be performed while forming the film using the sputtering method. Accordingly, an oxide semiconductor layer composed of a nano crystal oxide or an amorphous oxide can be readily obtained. Moreover, the above-described heat treatment is also advantageous in realizing a semiconductor device attaining both high electric field effect mobility and high reliability.

The heat treatment performed while forming the film by the sputtering method can be performed by heating the substrate during the formation of the film. The substrate temperature is preferably more than or equal to 100° C. and less than or equal to 250° C. The heat treatment time corresponds to the film formation time, and the film formation time can be, for example, about 10 seconds to 10 minutes although the film formation time depends on the film thickness of channel layer 14 to be formed.

As the material target of the sputtering method, an oxide sintered material containing In, W, and Zn can be used preferably. The oxide sintered material further preferably contains Zr. The oxide sintered material can be obtained by sintering a mixture of indium oxide powder, tungsten oxide powder and zinc oxide powder, as well as zirconium oxide powder added as required. The oxide sintered material may be obtained by performing a multi-stage sintering treatment (heat treatment) in the following manner: after calcinating a primary mixture of a part of the source material powder to obtain calcinated powder, the remaining source material powder is then added to the calcinated powder to obtain a secondary mixture, and the secondary mixture is sintered.

The oxide sintered material preferably includes an In₂O₃ crystal phase, which is a bixbyite type crystal phase. This is advantageous in realizing a semiconductor device attaining both high electric field effect mobility and high reliability. The term “bixbyite type crystal phase” is a general term encompassing a bixbyite crystal phase and a phase in which at least one of metallic elements other than In is included in at least a part of the bixbyite crystal phase and which has the same crystal structure as that of the bixbyite crystal phase. The bixbyite crystal phase is one of crystal phases of indium oxide (In₂O₃), represents a crystal structure defined in 6-0416 of the JCPDS card, and is also referred to as “C type rare earth oxide phase” (or “C rare earth structure phase”). As long as the crystal structure is exhibited, oxygen may lack or a metal may be dissolved in a solid state to result in a change in lattice constant.

The oxide sintered material preferably includes a ZnWO₄ type crystal phase. This is also advantageous in realizing a semiconductor device attaining both high electric field effect mobility and high reliability. The term “ZnWO₄ type crystal phase” is a general term encompassing a ZnWO₄ crystal phase and a phase in which at least one of elements other than Zn and W is included in at least a part of the ZnWO₄ crystal phase and which has the same crystal structure as that of the ZnWO₄ crystal phase. The ZnWO₄ crystal phase is a zinc tungstate compound crystal phase having a crystal structure represented by a space group P12/c1 (13) and having a crystal structure defined in 01-088-0251 of the JCPDS card. As long as the crystal structure is exhibited, oxygen may lack or a metal may be dissolved in a solid state to result in a change in lattice constant.

(1-4) Step of Forming Etch Stopper Layer 17

With reference to FIG. 8, this step is a step of forming etch stopper layer 17 on layer 20 including the oxide semiconductor. The material of etch stopper layer 17 is as described above. Etch stopper layer 17 is formed in contact with at least a portion of the second surface (surface opposite to the gate insulating layer 13 side) in layer 20 including the oxide semiconductor. Therefore, by forming etch stopper layer 17 having an oxygen atom content of more than or equal to 10 atom % and less than or equal to 80 atom %, the W element in layer 20 including the oxide semiconductor can be diffused in the direction of etch stopper layer 17 (toward the second surface of layer 20 including the oxide semiconductor) through a heat treatment, which is a subsequent step, whereby third region 3 and second region 2 satisfying W3>W2 can be formed.

Although the method for forming etch stopper layer 17 should not be particularly limited, the method for forming etch stopper layer 17 is preferably the plasma CVD (chemical vapor deposition) method, the sputtering method, the vacuum deposition method, or the like because a large area of etch stopper layer 17 can be uniformly formed and an insulating property can be secured by these methods.

(1-5) Step of Forming Contact Hole 17a

Since source electrode 15 and drain electrode 16 need to be in contact with channel layer 14, contact hole 17a is formed in etch stopper layer 17 after forming etch stopper layer 17 on layer 20 including the oxide semiconductor (FIG. 9). Examples of a method for forming contact hole 17a can include dry etching or wet etching. By etching etch stopper layer 17 by such a method to form contact hole 17a, the surface of layer 20 including the oxide semiconductor is exposed at the etched portion.

(1-6) Step of Forming Source Electrode and Drain Electrode

With reference to FIG. 10, this step is a step of forming source electrode 15 and drain electrode 16 on layer 20 including the oxide semiconductor and etch stopper layer 17 so as not to be in contact with each other. Specific examples of source electrode 15 and drain electrode 16 are as described above. Although a method for forming source electrode 15 and drain electrode 16 should not be particularly limited, the method for forming source electrode 15 and drain electrode 16 is preferably the vacuum deposition method, the sputtering method, or the like because large areas of source electrode 15 and drain electrode 16 can be uniformly formed on the main surface of substrate 11 having layer 20 including the oxide semiconductor formed thereon. Although a method for forming source electrode 15 and drain electrode 16 not to be in contact with each other should not be particularly limited, the method for forming source electrode 15 and drain electrode 16 not to be in contact with each other is preferably formation using an etching method employing a photoresist because large areas of uniform patterns of source electrode 15 and drain electrode 16 can be formed by the etching method.

(1-7) Step of Forming Passivation Layer 18

In the method for manufacturing semiconductor device 20 shown in FIG. 2, after source electrode 15 and drain electrode 16 are formed on layer 20 including the oxide semiconductor and etch stopper layer 17 so as not to be in contact with each other (FIG. 10), passivation layer 18 is formed on etch stopper layer 17, source electrode 15, and drain electrode 16 (FIG. 11). The material of passivation layer 18 is as described above.

Although a method for forming passivation film 18 should not be particularly limited, the method for forming passivation film 18 is preferably the plasma CVD (chemical vapor deposition) method, the sputtering method, the vacuum deposition method, or the like because a large area of passivation layer 18 can be uniformly formed and an insulating property is secured by these methods.

(1-8) Step of Performing Heat Treatment

This step is a step of obtaining semiconductor device 20 including channel layer 14 shown in FIG. 2 by performing heat treatment onto layer 20 including the oxide semiconductor at a temperature of more than or equal to 300° C. and preferably less than or equal to 500° C. This heat treatment is preferably performed after forming layer 20 including the oxide semiconductor and forming etch stopper layer 17, may be performed before or after the step of forming source electrode 15 and drain electrode 16, or may be performed after the step of forming passivation layer 18. The heat treatment can be performed by heating the substrate. The other heat treatment conditions are as described above.

Moreover, when gate insulating layer 13 is an oxygen-atom-containing layer having an oxygen atom content of more than or equal to 10 atom % and less than or equal to 80 atom % as described above, this heat treatment facilitates formation of first region 1 that satisfies W1/W2>1.0. When the oxygen atom content of gate insulating layer 13 is less than 10 atom %, the formation of first region 1 that satisfies W1/W2 1.0 is facilitated.

As described above, at least a part of W contained in layer 20 including the oxide semiconductor or third region 3 of channel layer 14 is preferably bound to at least one of silicon and/or aluminum included in the adjacent layer in contact with third region 3. Accordingly, the field effect mobility and reliability of the semiconductor device can be further improved. All of W contained in third region 3 does not need to be bound to silicon and/or aluminum, and a part of W may be bound to silicon and/or aluminum.

Next, the following describes a method for manufacturing semiconductor device 30 shown in FIG. 3. As in semiconductor device 30, a back channel etch (BCE) structure may be employed without forming etch stopper layer 17 and passivation film 18 may be formed directly on layer 20 including the oxide semiconductor, source electrode 15, and drain electrode 16. For passivation layer 18 in this case, reference is made to the above description regarding passivation layer 18 included in semiconductor device 20 shown in FIG. 2.

When manufacturing semiconductor device 30 shown in FIG. 3, after forming passivation layer 18, layer 20 including the oxide semiconductor is preferably subjected to a heat treatment at a temperature of more than or equal to 300° C. and preferably less than or equal to 500° C. The heat treatment can be performed by heating the substrate. By forming passivation layer 18 having an oxygen atom content of more than or equal to 10 atom % and less than or equal to 80 atom %, the W element in layer 20 including the oxide semiconductor can be diffused in the direction of etch stopper layer 17 (toward the second surface of layer 20 including the oxide semiconductor) by the heat treatment, whereby third region 3 and second region 2 satisfying W3>W2 can be formed.

Moreover, as described above, when gate insulating layer 13 is an oxygen-atom-containing layer having an oxygen atom content of more than or equal to 10 atom % and less than or equal to 80 atom %, this heat treatment facilitates the formation of first region 1 that satisfies W1/W2>1.0. When the oxygen atom content of gate insulating layer 13 is less than 10 atom %, the formation of first region 1 that satisfies W1/W2 1.0 is facilitated.

### EXAMPLES

### <Example 1 to Example 25, Comparative Examples 1 to 3, and Reference Example 1>

(1) Production of Semiconductor Device (TFT)

A TFT having a configuration similar to that of semiconductor device 30 shown in FIG. 3 was produced in the following procedure. First, with reference to FIG. 5, a synthetic quartz glass substrate having a size of 75 mm×75 mm×0.6 mm in thickness was prepared as substrate 11, and a Mo electrode having a thickness of 100 nm was formed as gate electrode 12 on substrate 11 by the sputtering method.

Next, with reference to FIG. 6, a SiOx layer, which was an amorphous oxide layer, or SiNy layer each having a thickness of 200 nm was formed as gate insulating layer 13 on gate electrode 12 by the plasma CVD method. In Table 1 below, respective materials of gate insulating layers 13 used in respective examples are described in the columns “GI Layer” and “Type”. Moreover, in Table 1, the respective oxygen atom contents of gate insulating layers 13 as measured by RBS are described in the columns “GI Layer” and “Oxygen Atom Content”.

When gate insulating layers 13 is a SiOx layer, the oxygen atom content is 55 atom % to 75 atom%. In this case, the W element would be diffused toward the gate insulating layer 13 side in layer 20 including the oxide semiconductor by the heat treatment, which was a subsequent step. Accordingly, W content W1 of first region 1 became larger than W content W2 of second region 2 in channel layer 14 included in the semiconductor device. On the other hand, when gate insulating layer 13 is a SiNy layer, the oxygen atom content is 0 atom%. In this case, the W element was not diffused unlike the case above, and W1 became smaller than W2 (W1/W2<1.0).

Next, with reference to FIG. 7, layer 20 including the oxide semiconductor having a thickness of 30 nm was formed on gate insulating film 13 by a DC (direct current) magnetron sputtering method. A flat surface of a target with a diameter of 4 inches (101.6 mm) was a sputtering surface. As the target, the oxide sintered material containing In, W, and Zn was used. This oxide sintered material was a sintered material for which indium oxide powder, tungsten oxide powder, zinc oxide powder, and zirconium oxide powder (except for Example 19) were prepared as a source material. The oxide sintered material included a bixbyite crystal phase (In₂O₃ crystal phase) and a ZnWO₄ crystal phase.

The following more specifically describes the formation of layer 20 including the oxide semiconductor. Substrate 11 having gate electrode 12 and gate insulating layer 13 formed thereon was disposed on a water-cooled substrate holder in a film formation chamber of a sputtering apparatus (not shown) such that gate insulating layer 13 was exposed. The target was disposed to face gate insulating layer 13 with a distance of 60 mm therebetween. With the film formation chamber being set to have a vacuum of about 6×10⁻⁵ Pa, the target was sputtered as follows.

First, in a state in which a shutter was placed between gate insulating layer 13 and the target, a mixed gas of Ar (argon) gas and O₂ (oxygen) gas was introduced into the film formation chamber until the pressure therein reached 0.5 Pa. An O₂ gas content in the mixed gas was 10 volume %. DC power of 200 W was applied to the target to cause sputtering discharge, thereby cleaning (pre-sputtering) the target surface for 5 minutes.

Next, under conditions that DC power of 200 W was applied to the same target and the atmosphere in the film formation chamber was maintained to be unchanged, the above-described shutter was removed, thereby forming layer 20 including the oxide semiconductor on gate insulating layer 13. It should be noted that no bias voltage was particularly applied to the substrate holder. Moreover, the substrate holder was water-cooled or heated to adjust the temperature of substrate 11 during the film formation. In each of the examples for which temperatures are described in the column “Heat Treatment during Film Formation” in Table 1 below, the substrate holder was heated at the described temperature to perform the heat treatment simultaneously with the film formation. In this case, the heat treatment time corresponds to the film formation time. In each of the examples, the film formation time was adjusted such that the film thickness of layer 20 including the oxide semiconductor became 30 nm. Moreover, when “Not Performed” is described in the column “Heat Treatment during Film Formation” in Table 1, no heat treatment was performed during the film formation. In this case, the substrate temperature during the film formation was about 20° C.

In the manner described above, layer 20 including the oxide semiconductor was formed by the DC (direct current) magnetron sputtering method employing the oxide sintered material target. Layer 20 including the oxide semiconductor served as channel layer 14 in the TFT.

Next, by etching a portion of formed layer 20 including the oxide semiconductor, patterning was performed to form regions corresponding to the source electrode formation portion, the drain electrode formation portion, and the channel portion. In the semiconductor device, the size of the main surface of each of the source electrode formation portion and the drain electrode formation portion was set at 60 μm×60 μm, channel length C_{L} thereof was set at 35 μm (with reference to FIG. 1, channel length C_{L} refers to a distance of the channel portion between source electrode 15 and drain electrode 16), and channel width C_{W} thereof was set at 50 μm (with reference to FIG. 1, channel width C_{W} refers to the width of the channel portion). 250 (at the longitudinal side)×250 (at the lateral side) of the channel portions were disposed at an interval of 300 μm within the substrate main surface of 75 mm×75 mm such that 250 (at the longitudinal side)×250 (at the lateral side) of TFTs were disposed at an interval of 300 μm within the substrate main surface of 75 mm×75 mm.

Layer 20 including the oxide semiconductor was partially etched in the following manner: substrate 11 having gate electrode 12, gate insulating layer 13, and layer 20 including the oxide semiconductor formed thereon in this order was immersed, at 40° C., in an etching aqueous solution prepared to have a volume ratio of oxalic acid: water=5:95.

Next, source electrode 15 and drain electrode 16 are then formed on layer 20 including the oxide semiconductor so as to be separated from each other.

Specifically, first, a resist (not shown) was applied to layer 20 including the oxide semiconductor, was exposed to light, and was developed to expose only respective main surfaces of regions corresponding to the source electrode formation portion and drain electrode formation portion of layer 20 including the oxide semiconductor. Next, Mo electrodes each having a thickness of 100 nm and respectively serving as source electrode 15 and drain electrode 16 were formed, using the sputtering method, on the respective main surfaces of the regions corresponding to the source electrode formation portion and drain electrode formation portion of layer 20 including the oxide semiconductor. Then, the resist on layer 20 including the oxide semiconductor was removed. One Mo electrode serving as source electrode 15 and one Mo electrode serving as drain electrode 16 are disposed for one channel portion such that 25 (at the longitudinal side)×25 (at the lateral side) of TFTs were disposed at an interval of 3 mm within the substrate main surface of 75 mm×75 mm.

Next, with reference to FIG. 3, passivation layer 18 was formed on layer 20 (channel layer 14) including the oxide semiconductor, source electrode 15 and drain electrode 16. Passivation film 18 had a configuration obtained by forming a SiOx film, which served as an amorphous oxide layer and had a thickness of 100 nm, by the plasma CVD method and then forming a SiNy film having a thickness of 200 nm by the plasma CVD method on the SiOx film. Alternatively, passivation film 18 had a configuration obtained by forming an AlxOy film, which served as an amorphous oxide layer and had a thickness of 100 nm, by the sputtering method and then forming a SiNx film having a thickness of 200 nm on the AlxOy film by the plasma CVD method. Alternatively, passivation film 18 had a configuration obtained by forming an SixOyNz film, which served as an amorphous oxide layer and had a thickness of 100 nm, by the sputtering method and then forming a SiNx film having a thickness of 200 nm on the SixOyNz film by the plasma CVD method. When the amorphous oxide layer was a SiOx layer, “SiOx” is described in the columns “PV Layer” and “Type” in Table 1 below. When the amorphous oxide layer was an AlxOy layer, “AlxOy” is described in the columns “PV Layer” and “Type”. When the amorphous oxide layer was a SixOyNz layer, “SixOyNz” is described in the columns “PV Layer” and “Type”. Moreover, in Table 1, the oxygen atom content of passivation layer 18 (amorphous oxide layer) as measured by RBS is described in the columns “PV Layer” and “Oxygen Atom Content”.

Next, passivation layer 18 on source electrode 15 and drain electrode 16 was etched by reactive ion etching to form a contact hole, thereby exposing portions of the surfaces of source electrode 15 and drain electrode 16.

Finally, heat treatments were performed in all the examples. Each of the heat treatments was:

1) a heat treatment performed at 350° C. for 30 minutes to 120 minutes in a nitrogen atmosphere; or

2) a heat treatment (first stage) performed at 300° C. for 60 minutes to 120 minutes under an atmospheric pressure in an atmospheric air, and a heat treatment (second stage) thereafter performed at 350° C. for 30 minutes to 120 minutes in a nitrogen atmosphere.

However, in Comparative Example 3, the temperature of the second stage of the heat treatment was set at 150° C., and in reference example 1, the temperature of the second stage of the heat treatment was set at 520° C.

When the heat treatment of 2) was performed, the treatment time of the first stage of the heat treatment is described in the columns “Heat Treatment after Film Formation” and “First Stage Treatment Time” in Table 1 below. The treatment time of the second stage is described in the columns “Heat Treatment after Film Formation” and “Second Stage Treatment Time” in Table 1 below. When the heat treatment of 1) was performed, the treatment time is described in the columns “Heat Treatment after Film Formation” and “Second Stage Treatment Time” and “Not Performed” is described in the column “First Stage”. In this way, there were obtained TFTs each including channel layer 14 including the oxide semiconductor containing In, W, and Zn.

(2) Measurement of In Content, W Content, Zn Content, Zn/W Ratio, W3/W2, W1/W2, Zr Content, and Crystal Structure of Channel Layer

Table 2 shows a result of measuring, in accordance with the above-described measurement method and definition, the In content (the content of In relative to the total of In, W, and Zn in atom %), the W content, the Zn content, the Zn/W ratio, W3/W2, W1/W2, the Zr content, and the crystal structure of the channel layer.

The In content, W content, Zn content, and Zn/W ratio were measured by RBS (Rutherford back-scattering analysis). W3/W2, W1/W2, and the Zr content were calculated by measuring the number of counts of secondary ions originated from the W element using a secondary ion mass spectrometer (SIMS). In the column “Crystal Structure” in Table 2, “N” indicates that channel layer 14 is composed of the nano crystal oxide, and “A” indicates that channel layer 14 is composed of the amorphous oxide.

(3) Measurement of Electric Resistivity of Channel Layer

A measurement needle was brought into contact with source electrode 15 and drain electrode 13. Next, source-drain current I_{ds} was measured while changing applied voltage between the source and drain electrodes from 1 V to 20 V. An inclination of a graph of I_{ds}-V_{g}, represents resistance R. Based on this resistance R, channel length C_{L} (35 μm), channel width C_{W} (50 μm), and film thickness t, the electric resistivity of channel layer 14 can be found as R×C_{W}×t/C_{L}. It was confirmed that all the channel layers 14 of the present examples had electric resistivities of more than or equal to 10⁻¹ Ωcm.

(4) Measurement of Electron Carrier Concentration of Channel Layer

Hall effect measurement was performed to measure an electron carrier concentration. Each of measurement samples was produced in the following procedure. First, the above-described gate insulating layer (the same material for the respective examples) was formed on a square glass substrate (1 cm×1 cm×0.5 mm in thickness), and then the layer including the oxide semiconductor (the same material for the respective examples) was formed. The film thickness of the layer including the oxide semiconductor was 100 nm. Then, the passivation layer (the same material for the respective examples) was formed, a contact hole was formed at each of the four corners of the substrate, and a Mo electrode having a square size of 1 mm×1 mm in the contact hole was formed to have a film thickness of 100 nm. Finally, the above-described heat treatment (the same heat treatment for the respective examples) was performed, thereby obtaining a measurement sample. The Hall effect measurement was performed using this measurement sample to measure an electron carrier concentration.

(5) Evaluation on Characteristics of Semiconductor Device

First, a measurement needle was brought into contact with each of gate electrode 12, source electrode 15, and drain electrode 16. A source-drain voltage V_{ds} of 0.2 V was applied between source electrode 15 and drain electrode 16, a source-gate voltage V_{gs} applied between source electrode 15 and gate electrode 12 was changed from −30 V to 20 V, and a source-drain current I_{ds} on this occasion was measured. Then, a relation between source-gate voltage V_{gs} and a square root ((I_{ds})^{1/2}) of source-drain current I_{ds} was illustrated in a graph (hereinafter, this graph is also referred to as “V_{gs}-(I_{ds})^{1/2} curve”). A threshold voltage Vₜₕ was represented by a point (x intercept) at which the x axis (V_{gs}) crossed a line tangential to a point at which the inclination of a tangential line drawn to the V_{gs}-(I_{ds})^{1/2} curve was the maximum. A result of measurement of threshold voltage Vₜₕ is shown in Table 3.

Moreover, gₘ was derived by differentiating source-drain current I_{ds} with respect to source-gate voltage V_{gs} in accordance with the following formula [a]:

gₘ=dI_{ds}/dV_{gs} [a]

Then, the value of gₘ in V_{gs}=10.0 V was used to determine an electric field effect mobility μ_{fe} based on the following formula [b]:

μ_{fe}=gₘ ·C_{L}/(C_{W}·Cᵢ·V_{ds}) [b]

Channel length C_{L} in the above-described formula [b] was 35 μm, and channel width C_{W} was 50 μm. Moreover, capacitance Cᵢ of gate insulating layer 13 was set at 3.4×10⁻⁸F/cm², and source-drain voltage V_{ds} was set at 0.2 V. Table 3 shows a result of measurement of electric field effect mobility μ_{fe}.

Moreover, off current was obtained as the average value of I_{ds} at 21 points obtained when changing source-gate voltage V_{gs} from −2.0 V to 0 V by 0.1 V in a step-by-step manner with the source-drain voltage V_{ds} being set at 5.1 V. A result thereof is shown in Table 3.

Further, the following reliability evaluation test was performed. Source-gate voltage V_{gs} applied between source electrode 15 and gate electrode 12 was fixed to −32 V and was continued to be applied for 1 hour. After 1s, 10s, 100s, 300s and 3600s from the start of the application, threshold voltages Vₜₕ were determined by the above-described method, and a difference ΔVₜₕ was determined between maximum threshold voltage Vₜₕ and minimum threshold voltage Vₜₕ. A result thereof is shown in Table 3. It is determined that as ΔVₜₕ is smaller, the reliability is higher.

TABLE 1

| | Semiconductor Device Manufacturing Process | | | | | | |
|---|---|---|---|---|---|---|---|
| | GI Layer | | PV Layer | | Heat Treatment | Heat Treatment after Film Formation | |
| | | Oxygen Atom | | Oxygen Atom | during Film | First Stage | Second Stage |
| | | Content | | Content | Forming | Treatment Time | Treatment Time |
| | Type | Atom % | Type | Atom % | ° C. | hr | hr |
| Example 1 | SiOx | 60 | AlxOy | 60 | Not Performed | 1 | 1 |
| Example 2 | SiOx | 60 | AlxOy | 60 | Not Performed | 1 | 1 |
| Example 3 | SiOx | 60 | AlxOy | 60 | Not Performed | 1 | 1 |
| Example 4 | SiOx | 60 | AlxOy | 60 | Not Performed | 1 | 1 |
| Example 5 | SixOyNz | 9 | SixOyNz | 23 | Not Performed | Not Performed | 2 |
| Example 6 | SixOyNz | 9 | SixOyNz | 23 | Not Performed | Not Performed | 2 |
| Example 7 | SixOyNz | 9 | SixOyNz | 23 | Not Performed | Not Performed | 2 |
| Example 8 | SixOyNz | 9 | SixOyNz | 23 | Not Performed | Not Performed | 2 |
| Example 9 | SixNy | 0 | SiOx | 67 | Not Performed | Not Performed | 2 |
| Example 10 | SixNy | 0 | SiOx | 67 | Not Performed | Not Performed | 2 |
| Example 11 | SixNy | 0 | SiOx | 67 | Not Performed | Not Performed | 2 |
| Example 12 | SixNy | 0 | SiOx | 67 | Not Performed | Not Performed | 2 |
| Example 13 | SiOx | 67 | SiOx | 67 | Not Performed | Not Performed | 1.5 |
| Example 14 | SiOx | 67 | SiOx | 67 | Not Performed | Not Performed | 1.5 |
| Example 15 | SiOx | 67 | SiOx | 67 | Not Performed | Not Performed | 1.5 |
| Example 16 | SiOx | 67 | SiOx | 67 | Not Performed | Not Performed | 1.5 |
| Example 17 | SiOx | 67 | SiOx | 67 | Not Performed | Not Performed | 1.5 |
| Example 18 | SiOx | 67 | SiOx | 67 | 150 | Not Performed | 1.5 |
| Example 19 | SiOx | 67 | SiOx | 67 | Not Performed | Not Performed | 1.5 |
| Example 20 | SiOx | 67 | SiOx | 67 | Not Performed | Not Performed | 1.5 |
| Example 21 | SiOx | 67 | SiOx | 67 | Not Performed | Not Performed | 1.5 |
| Example 22 | SiOx | 67 | SiOx | 67 | Not Performed | Not Performed | 1.5 |
| Example 23 | SiOx | 67 | SiOx | 67 | Not Performed | Not Performed | 1.5 |
| Example 24 | SiOx | 67 | SiOx | 67 | Not Performed | Not Performed | 1.5 |
| Example 25 | SiOx | 67 | SiOx | 67 | Not Performed | Not Performed | 1.5 |
| Comparative | SiOx | 67 | SiOx | 67 | Not Performed | Not Performed | 1.5 |
| Example 1 | | | | | | | |
| Comparative | SiOx | 67 | SiOx | 67 | Not Performed | Not Performed | 1.5 |
| Example 2 | | | | | | | |
| Comparative | SiOx | 67 | SiOx | 67 | Not Performed | Not Performed | 1.5 |
| Example 3 | | | | | | | |
| Reference | SiOx | 67 | SiOx | 67 | Not Performed | Not Performed | 1.5 |
| Example 1 | | | | | | | |

TABLE 2

| | Characteristics of Channel Layer | | | | | | | | | |
|---|---|---|---|---|---|---|---|---|---|---|
| | In | W | Zn | | | | Zr | Electric | | |
| | Content | Content | Content | Zn/W | | | Concentration | Resistivity | Electron Carrier | Crystal |
| | Atom % | Atom % | Atom % | Ratio | W3/W2 | W1/W2 | atms/cm³ | Ωcm | Concentration/cm³ | Structure |
| Example 1 | 80.4 | 0.6 | 19.0 | 31.7 | 2.1 | 3.2 | 5.2 × 10¹⁹ | 1 × 10³ | 9 × 10¹⁸ | N |
| Example 2 | 80.0 | 1.0 | 19.0 | 19.0 | 2.3 | 3.1 | 8.3 × 10¹⁹ | 4 × 10³ | 6 × 10¹⁷ | N |
| Example 3 | 79.5 | 1.5 | 19.0 | 12.7 | 2.1 | 3.0 | 5.6 × 10¹⁹ | 6 × 10³ | 7 × 10¹⁶ | N |
| Example 4 | 79.0 | 2.0 | 19.0 | 9.5 | 2.2 | 3.1 | 4.8 × 10¹⁹ | 1 × 10⁴ | 3 × 10¹⁶ | N |
| Example 5 | 80.4 | 0.6 | 19.0 | 31.7 | 1.4 | 0.9 | 5.2 × 10¹⁹ | 1 × 10³ | 9 × 10¹⁸ | N |
| Example 6 | 80.0 | 1.0 | 19.0 | 19.0 | 1.3 | 0.8 | 8.3 × 10¹⁹ | 4 × 10³ | 6 × 10¹⁷ | N |
| Example 7 | 79.5 | 1.5 | 19.0 | 12.7 | 1.5 | 0.8 | 4.8 × 10¹⁹ | 6 × 10³ | 7 × 10¹⁶ | N |
| Example 8 | 79.0 | 2.0 | 19.0 | 9.5 | 1.4 | 0.8 | 3.1 × 10¹⁹ | 1 × 10⁴ | 3 × 10¹⁶ | N |
| Example 9 | 80.4 | 0.6 | 19.0 | 31.7 | 3.1 | 0.6 | 2.8 × 10¹⁹ | 1 × 10³ | 9 × 10¹⁸ | N |
| Example 10 | 80.0 | 1.0 | 19.0 | 19.0 | 3.4 | 0.5 | 8.3 × 10¹⁹ | 4 × 10³ | 6 × 10¹⁷ | N |
| Example 11 | 79.5 | 1.5 | 19.0 | 12.7 | 3.1 | 0.4 | 6.7 × 10¹⁹ | 6 × 10³ | 7 × 10¹⁶ | N |
| Example 12 | 79.0 | 2.0 | 19.0 | 9.5 | 3.2 | 0.5 | 5.4 × 10¹⁹ | 1 × 10⁴ | 3 × 10¹⁶ | N |
| Example 13 | 98.2 | 0.6 | 1.2 | 2.0 | 3.1 | 3.0 | 3.6 × 10¹⁹ | 1 × 10³ | 9 × 10¹⁸ | N |
| Example 14 | 80.4 | 0.6 | 19.0 | 31.7 | 3.2 | 3.1 | 2.8 × 10¹⁹ | 1 × 10³ | 9 × 10¹⁸ | N |
| Example 15 | 94.0 | 1.0 | 5.0 | 5.0 | 3.0 | 3.0 | 4.8 × 10¹⁹ | 4 × 10³ | 6 × 10¹⁷ | N |
| Example 16 | 89.0 | 1.0 | 10.0 | 10.0 | 3.2 | 3.1 | 7.2 × 10¹⁹ | 4 × 10³ | 6 × 10¹⁷ | N |
| Example 17 | 80.0 | 1.0 | 19.0 | 19.0 | 3.1 | 3.0 | 8.3 × 10¹⁹ | 4 × 10³ | 6 × 10¹⁷ | N |
| Example 18 | 80.0 | 1.0 | 19.0 | 19.0 | 3.0 | 2.9 | 8.3 × 10¹⁹ | 2 × 10³ | 9 × 10¹⁷ | A |
| Example 19 | 80.0 | 1.0 | 19.0 | 19.0 | 3.0 | 2.9 | Not Performed | 5 × 10³ | 3 × 10¹⁷ | N |
| Example 20 | 79.5 | 1.5 | 19.0 | 12.7 | 3.3 | 3.2 | 6.4 × 10¹⁹ | 6 × 10³ | 7 × 10¹⁶ | N |
| Example 21 | 79.0 | 2.0 | 19.0 | 9.5 | 3.4 | 3.3 | 2.1 × 10¹⁹ | 1 × 10⁴ | 3 × 10¹⁶ | N |
| Example 22 | 76.0 | 5.0 | 19.0 | 3.8 | 3.2 | 3.3 | 8.2 × 10¹⁹ | 3 × 10⁴ | 2 × 10¹⁶ | N |
| Example 23 | 74.0 | 7.0 | 19.0 | 2.7 | 3.0 | 3.0 | 7.4 × 10¹⁹ | 5 × 10⁴ | 1 × 10¹⁶ | N |
| Example 24 | 58.0 | 1.0 | 41.0 | 41.0 | 3.3 | 3.1 | 8.3 × 10¹⁹ | 8 × 10³ | 6 × 10¹⁸ | N |
| Example 25 | 79.0 | 1.0 | 20.0 | 20.0 | 3.2 | 3.1 | 8.3 × 10¹⁹ | 5 × 10³ | 3 × 10¹⁸ | N |
| Comparative | 80.5 | 0.5 | 19.0 | 38.0 | 3.2 | 3.1 | 8.3 × 10¹⁹ | 3 | 3 × 10²¹ | N |
| Example 1 | | | | | | | | | | |
| Comparative | 72.9 | 8.1 | 19.0 | 2.3 | 3.3 | 3.2 | 8.3 × 10¹⁹ | 1 × 10⁴ | 3 × 10¹⁵ | N |
| Example 2 | | | | | | | | | | |
| Comparative | 80.0 | 1.0 | 19.0 | 19.0 | 1.0 | 1.0 | 8.3 × 10¹⁹ | 4 × 10³ | 6 × 10¹⁷ | N |
| example 3 | | | | | | | | | | |
| Reference | 80.0 | 1.0 | 19.0 | 19.0 | 4.1 | 4.2 | 8.3 × 10¹⁹ | Cannot be | Cannot be | N |
| Example 1 | | | | | | | | Measured | Measured | |

TABLE 3

| | Characteristics of Semiconductor Device | | | |
|---|---|---|---|---|
| | | | Mobility | |
| | Off Current A | Vth V | cm²/Vs | ΔVth V |
| Example 1 | 1 × 10¹³ | 1.2 | 35 | 0.06 |
| Example 2 | 1 × 10¹³ | 1.5 | 34 | 0.04 |
| Example 3 | 1 × 10¹³ | 1.8 | 30 | 0.04 |
| Example 4 | 1 × 10¹³ | 2.0 | 29 | 0.04 |
| Example 5 | 2 × 10¹³ | 0.2 | 38 | 0.15 |
| Example 6 | 2 × 10¹³ | 0.5 | 37 | 0.12 |
| Example 7 | 2 × 10¹³ | 0.7 | 35 | 0.12 |
| Example 8 | 2 × 10¹³ | 0.9 | 34 | 0.12 |
| Example 9 | 6 × 10¹³ | 0.7 | 48 | 0.15 |
| Example 10 | 6 × 10¹³ | 0.9 | 46 | 0.13 |
| Example 11 | 6 × 10¹³ | 1.2 | 44 | 0.13 |
| Example 12 | 6 × 10¹³ | 1.5 | 42 | 0.13 |
| Example 13 | 1 × 10¹³ | 0.4 | 36 | 0.08 |
| Example 14 | 1 × 10¹³ | 1.4 | 34 | 0.05 |
| Example 15 | 1 × 10¹³ | 0.6 | 32 | 0.05 |
| Example 16 | 1 × 10¹³ | 0.8 | 31 | 0.05 |
| Example 17 | 1 × 10¹³ | 1.8 | 30 | 0.05 |
| Example 18 | 1 × 10¹³ | 1.8 | 31 | 0.06 |
| Example 19 | 1 × 10¹³ | 1.8 | 30 | 0.09 |
| Example 20 | 1 × 10¹³ | 1.7 | 30 | 0.05 |
| Example 21 | 1 × 10¹³ | 1.9 | 29 | 0.05 |
| Example 22 | 1 × 10¹³ | 2.2 | 27 | 0.05 |
| Example 23 | 1 × 10¹³ | 3.5 | 25 | 0.05 |
| Example 24 | 1 × 10¹³ | 2.4 | 21 | 0.05 |
| Example 25 | 1 × 10¹³ | 1.9 | 29 | 0.05 |
| Comparative | Element Not Operated | | | |
| Example 1 | | | | |
| Comparative | 1 × 10¹³ | 15.0 | Cannot be | 0.35 |
| Example 2 | | | Calculated | |
| Comparative | 1 × 10¹³ | 0.6 | 37 | 0.42 |
| Example 3 | | | | |

| | |
|---|---|
| Reference | Element Not Operated |
| Example 1 | |

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first region of channel layer; 2: second region of channel layer; 3: third region of channel layer; 10, 20, 30: semiconductor device (TFT); 11: substrate; 12: gate electrode; 13: gate insulating layer; 14: channel layer; 15: source electrode; 16: drain electrode; 17: etch stopper layer; 17a: contact hole; 18: passivation layer; 20: layer including oxide semiconductor.

1. A semiconductor device comprising a gate insulating layer, and a channel layer disposed in contact with the gate insulating layer,
the channel layer including an oxide semiconductor containing indium, tungsten, and zinc,
a content of the tungsten relative to a total of the indium, the tungsten, and the zinc in the channel layer being more than 0.01 atom % and less than or equal to 8.0 atom %,
the channel layer including a first region, a second region, and a third region in this order, the first region including a first surface in contact with the gate insulating layer, the third region including a second surface opposite to the first surface,
a content W3 (atom %) of the tungsten relative to a total of the indium, the tungsten, and the zinc in the third region being larger than a content W2 (atom %) of the tungsten relative to a total of the indium, the tungsten, and the zinc in the second region.

2. The semiconductor device according to claim 1, wherein a ratio (W3/W2) of the W3 and the W2 is more than 1.0 and less than or equal to 4.0.

3. The semiconductor device according to claim 1, wherein a content W1 (atom %) of the tungsten relative to a total of the indium, the tungsten, and the zinc in the first region is larger than the W2 (atom %).

4. The semiconductor device according to claim 1, wherein a content W1 (atom %) of the tungsten relative to a total of the indium, the tungsten, and the zinc in the first region is equal to or less than the W2 (atom %).

5. The semiconductor device according to 4-claim 1, wherein
a content of the zinc relative to the total of the indium, the tungsten, and the zinc in the channel layer is more than or equal to 1.2 atom % and less than 40 atom %, and
an atomic ratio (zinc/tungsten) of the zinc and the tungsten in the channel layer is more than 1.0 and less than 60.

6. The semiconductor device according to claim 1, wherein the channel layer has an electric resistivity of more than or equal to 10⁻¹ Ωcm.

7. The semiconductor device according to claim 1, wherein the channel layer has an electron carrier concentration of more than or equal to 1×10¹³/cm³ and less than or equal to 9×10¹⁸/cm³.

8. The semiconductor device according to claim 1, wherein
the channel layer further contains zirconium, and
a content of the zirconium is more than or equal to 1×10¹⁷ atms/cm³ and less than or equal to 1×10²⁰ atms/cm³.

9. The semiconductor device according to claim 1, wherein the channel layer is composed of a nano crystal oxide or an amorphous oxide.

10. The semiconductor device according to claim 1, wherein the third region is in contact with a layer having an oxygen atom content of more than or equal to 10 atom % and less than or equal to 80 atom %.

11. The semiconductor device according to claim 1, wherein the gate insulating layer has an oxygen atom content of more than or equal to 10 atom % and less than or equal to 80 atom %.

12. The semiconductor device according to claim 1, wherein the gate insulating layer has an oxygen atom content of more than or equal to 0 atom % and less than 10 atom %.

13. A method for manufacturing the semiconductor device recited in claim 1, the method comprising:
forming a layer including the oxide semiconductor so that the layer is in contact with the gate insulating layer; and
performing a heat treatment onto the layer including the oxide semiconductor at a temperature of more than or equal to 300° C.

14. The method for manufacturing the semiconductor device according to claim 13, wherein the temperature of the heat treatment is less than or equal to 500° C.
